(19) United States
(12) Patent Application Publication
(10) Pub. No.: US 2022/0254596 A1
(43) Pub. Date: Aug. 11, 2022

(54) ELECTRON GUN AND ELECTRON BEAM IRRADIATION DEVICE

(71) Applicant: NuFlare Technology, Inc., Yokohama-shi (JP)

(72) Inventors: Atsushi ANDO, Edogawa-ku (JP); Shigeru WAKAYAMA, Minato-ku (JP)

(73) Assignee: NuFlare Technology, Inc., Yokohama-shi (JP)

(21) Appl. No.: 17/629,660

(22) PCT Filed: Aug. 13, 2020
(86) PCT No.: PCT/JP2020/030773

§ 371 Date: Jan. 24, 2022

(30) Foreign Application Priority Data
Aug. 28, 2019 (JP) 2019-155279

(51) Int. Cl. H01J 37/09; H01J 37/26; H01J 37/073

(52) U.S. Cl. CPC H01J 37/09; H01J 37/261; H01J 2237/2817; H01J 2237/0453; H01J 37/073

(57) ABSTRACT

An electron gun according to one aspect of the present invention includes an emission source configured to emit an electron beam, an aperture array substrate, where a plurality of passage holes are formed, configured to form multiple beams by letting portions of the electron beam individually pass through the plurality of passage holes, and a first electrode, where a first opening through which the electron beam can pass is formed, configured to include an opposing plane which is located at a side of the emission source with respect to the aperture array substrate and facing a surface of the aperture array substrate and whose outer diameter is smaller than an outer diameter of the aperture array substrate, the first electrode configured to be applied with a first control potential.

### TECHNICAL FIELD

This application is based upon and claims the benefit of priority from Japanese Patent Application No. 2019-155279 filed on Aug. 28, 2019 in Japan, the contents of which are incorporated herein.

The present invention relates to an electron gun and an electron beam irradiation apparatus. For example, it relates to an electron gun which emits multiple beams mounted in an apparatus for applying multiple electron beam irradiation.

### BACKGROUND ART

With recent progress in high integration and large capacity of the Large Scale Integrated circuits (LSI), the circuit line width required for semiconductor elements is becoming increasingly narrower. Since LSI manufacturing requires an enormous production cost, it is essential to improve the yield. However, as typified by 1 gigabit DRAMs (Random Access Memories), patterns which make up LSI are reduced from the order of submicrons to nanometers. Also, in recent years, with miniaturization of dimensions of LSI patterns formed on a semiconductor wafer, dimensions to be detected as a pattern defect have become extremely small. Therefore, the pattern inspection apparatus for inspecting defects of ultrafine patterns exposed/transferred onto a semiconductor wafer needs to be highly accurate.

As an inspection method, there is known a method of comparing a measured image acquired by imaging a pattern formed on a substrate, such as a semiconductor wafer or a lithography mask, with design data or with another measured image acquired by imaging the identical pattern on the substrate. For example, as a pattern inspection method, there are “die-to-die inspection” and “die-to-database inspection”. The “die-to-die inspection” method compares data of measured images acquired by imaging identical patterns at different positions on the same substrate. The “die-to-database inspection” method generates, based on pattern design data, design image data (reference image), and compares it with a measured image being measured data acquired by imaging a pattern. Acquired images are transmitted as measured data to a comparison circuit. After performing alignment between the images, the comparison circuit compares the measured data with reference data according to an appropriate algorithm, and determines that there is a pattern defect if the compared data do not match each other.

With respect to the pattern inspection apparatus described above, in addition to the apparatus that irradiates an inspection target substrate with laser beams in order to obtain a transmission image or a reflection image, there has been developed another inspection apparatus that acquires a pattern image by scanning an inspection target substrate with electron beams and detecting secondary electrons emitted from the inspection target substrate due to the irradiation with the electron beams. With regard to inspection apparatuses using electron beams, development is also in progress for apparatuses using multiple beams. For example, electron beams are emitted from a Schottky type electron gun. In the Schottky type electron gun, electrons emitted from the emitter using the Schottky effect are extracted by the extractor (extraction electrode) and accelerated and converged by multi-stage electrodes, while being suppressed by the suppressor. Aperture substrates, in which passage holes for generating multiple beams are formed, are disposed each between the multi-stage electrodes. Thereby, the Schottky type electron gun that emits multiple beams has been examined (e.g., refer to Non-Patent Literature 1). However, there is a problem that an electric discharge due to electrode concentration might be generated at the portion where the aperture substrate is mounted on the electrode.

### CITATION LIST

### Patent Literature

Non-patent Literature 1:
Multi-Beam Scanning Electron Microscope Design,
Microsc. Microanal. 22 (Suppl 3), 2016

### SUMMARY OF INVENTION

### Technical Problem

One aspect of the present invention provides an electron gun that can avoid an electric discharge due to electrode concentration at the portion where an aperture array mechanism is mounted on the electrode.

### Solution to Problem

According to one aspect of the present invention, an electron gun includes
an emission source configured to emit an electron beam;
an aperture array substrate, where a plurality of passage holes are formed, configured to form multiple beams by letting portions of the electron beam individually pass through the plurality of passage holes; and
a first electrode, where a first opening through which the electron beam can pass is formed, configured to include an opposing plane which is located at a side of the emission source with respect to the aperture array substrate and facing a surface of the aperture array substrate and whose outer diameter is smaller than an outer diameter of the aperture array substrate, the first electrode configured to be applied with a first control potential.

According to another aspect of the present invention, an electron beam irradiation apparatus includes
an electron gun configured to include an emission source to emit an electron beam, an aperture array substrate, where a plurality of openings are formed, configured to form multiple beams by letting portions of the electron beam individually pass through the plurality of openings, and a first electrode configured to include an opposing plane which is located at a side of the emission source with respect to the aperture array substrate and facing a surface of the aperture array substrate and whose outer diameter is smaller than an outer diameter of the aperture array substrate, and to provide an electric field between the first electrode and the aperture array substrate; and
an electron optical system configured to lead the multiple beams emitted from the electron gun to a target object.

According to yet another aspect of the present invention, an electron gun includes
an emission source configured to emit an electron beam; and
multi-stage electrodes configured to provide an electric field to the electron beam, wherein
a plurality of passage holes which generate multiple beams by letting portions of the electron beam individually pass through the plurality of passage holes are formed at a center of one of the multi-stage electrodes, and
openings through which the electron beam can pass individually are formed at centers of remaining electrodes in the multi-stage electrodes.

### Advantageous Effects of Invention

According to one aspect of the present invention, it is possible to avoid an electric discharge due to electrode concentration at the portion where an aperture array mechanism is mounted on the electrode.

### BRIEF DESCRIPTION OF DRAWINGS

FIG. 1 is a diagram showing an example of a configuration of a pattern inspection apparatus according to an embodiment 1.

FIG. 2 is a diagram illustrating an example of a sectional configuration of a shaping aperture array substrate and neighboring electrodes in multi-stage electrodes in an electron gun according to the embodiment 1.

FIG. 3 is a diagram illustrating an example of a sectional configuration of a shaping aperture array substrate and neighboring electrodes in multi-stage electrodes in an electron gun according to a comparative example of the embodiment 1.

FIG. 4 is a diagram illustrating an example of an electric field near a shaping aperture array substrate in multi-stage electrodes in an electron gun according to a comparative example of the embodiment 1.

FIG. 5 is a diagram illustrating an example of an electric field near a shaping aperture array substrate in multi-stage electrodes in an electron gun according to the embodiment 1.

FIG. 6 is a diagram showing an example of a plurality of chip regions formed on a semiconductor substrate, according to the embodiment 1.

FIG. 7 is a diagram illustrating a scanning operation with multiple beams according to the embodiment 1.

FIG. 8 is a diagram showing an example of an internal configuration of a comparison circuit according to the embodiment 1.

FIG. 9 is a diagram illustrating an example of a sectional configuration of a shaping aperture array substrate and neighboring electrodes in multi-stage electrodes in an electron gun according to an embodiment 2.

FIG. 10 is a diagram illustrating an example of an electric field near a shaping aperture array substrate in multi-stage electrodes in an electron gun according to the embodiment 2.

FIG. 11 is a diagram illustrating an example of a sectional configuration of a shaping aperture array mechanism and neighboring electrodes in multi-stage electrodes in an electron gun according to an embodiment 3.

### DESCRIPTION OF EMBODIMENTS

Embodiments below describe an inspection apparatus which uses electron beams as an electron beam irradiation apparatus. However, it is not limited thereto. Any apparatus, such as a writing apparatus, which irradiates a target substrate and the like with electron beams emitted from an electron gun can be the electron beam irradiation apparatus.

### Embodiment 1

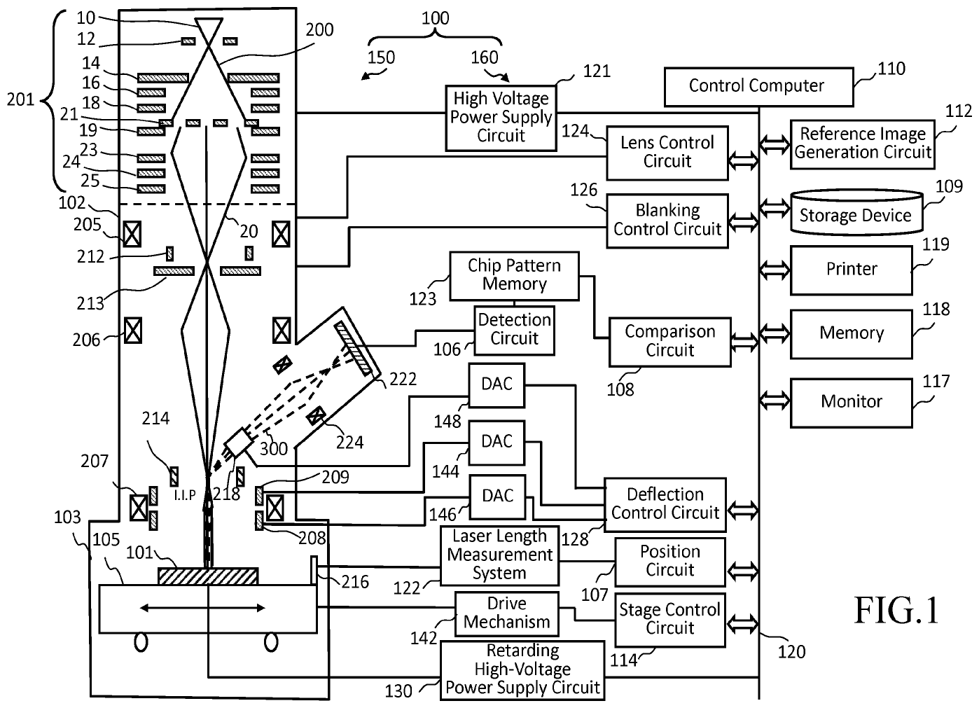

FIG. 1 is a diagram showing an example of a configuration of a pattern inspection apparatus according to an embodiment 1. In FIG. 1, an inspection apparatus 100 for inspecting a pattern formed on the substrate is an example of a multi electron beam inspection apparatus. The inspection apparatus 100 includes an image acquisition mechanism 150 (secondary electron image acquisition mechanism) and a control system circuit 160. The image acquisition mechanism 150 includes an electron gun 201, an electron beam column 102 (electron optical column) and an inspection chamber 103. The electron gun 201 is mounted on the electron beam column 102.

The electron gun 201 includes a vacuum vessel 11 which can respond to the vacuum state. In the vacuum vessel 11, there are disposed a cathode 10 (emitter) (emission source), a suppressor 12, an extractor 14, multi-stage electrodes 16, 18, 19, 23, 24, and 25, and a shaping aperture array substrate 21. The shaping aperture array substrate 21 is supported by the electrode 19, which is arranged close to the intermediate position, in the multi-stage electrodes 16, 18, 19, 23, 24, and 25. At the center of each of the multi-stage electrodes 16, 18, 19, 23, 24, and 25, there is formed an opening through which an electron beam or the entire multiple primary electron beams can pass. As the cathode 10, it is preferable to use a ZrO/W emitter formed by a tungsten (W) <100> single crystal coated with zirconium dioxide (ZrO), for example. The suppressor 12, the extractor 14, and the multi-stage electrodes 16, 18, 19, 23, 24, and 25 are formed from a conductive material. For example, they are formed from a metal material. Alternatively, an insulation material whose surface is coated with a conductive material may be used. The shaping aperture array substrate 21 is mainly configured by, for example, a silicon substrate. The exposed surface of the silicon substrate is coated with a metal material, for example.

In the electron beam column 102, there are disposed an electromagnetic lens 205, a bundle blanking deflector 212, a limiting aperture substrate 213, an electromagnetic lens 206, an electromagnetic lens 207 (objective lens), a main deflector 208, a sub deflector 209, a beam separator 214, a deflector 218, an electromagnetic lens 224, and a multi-detector 222. In the example of FIG. 1, the primary electron optical system, which irradiates a substrate 101 with multiple primary electron beams 20, is composed of the electromagnetic lens 205, the bundle blanking deflector 212, the limiting aperture substrate 213, the electromagnetic lens 206, the electromagnetic lens 207 (objective lens), the main deflector 208, and the sub deflector 209. The secondary electron optical system, which irradiates the multi-detector 222 with multiple secondary electron beams 300, is composed of the electromagnetic lens 207, the beam separator 214, the deflector 218, and the electromagnetic lens 224.

In the inspection chamber 103, there is disposed a stage 105 movable at least in the x and y directions. The substrate 101 (target object) to be an inspection target is mounted on the stage 105. The substrate 101 may be an exposure mask substrate, or a semiconductor substrate such as a silicon wafer. In the case of the substrate 101 being a semiconductor substrate, a plurality of chip patterns (wafer dies) are formed on the semiconductor substrate. In the case of the substrate 101 being an exposure mask substrate, a chip pattern is formed on the exposure mask substrate. The chip pattern is composed of a plurality of figure patterns. When the chip pattern formed on the exposure mask substrate is exposed/transferred onto the semiconductor substrate a plurality of times, a plurality of chip patterns (wafer dies) are formed on the semiconductor substrate. The case of the substrate 101 being a semiconductor substrate is mainly described below. The substrate 101 is placed with its pattern-forming surface facing upward on the stage 105, for example. Further, on the stage 105, there is disposed a mirror 216 which reflects a laser beam for measuring a laser length emitted from a laser length measuring system 122 arranged outside the inspection chamber 103. The multi-detector 222 is connected, at the outside of the electron beam column 102, to a detection circuit 106.

In the control system circuit 160, a control computer 110 which controls the whole of the inspection apparatus 100 is connected, through a bus 120, to a high-voltage power supply circuit 121, a position circuit 107, a comparison circuit 108, a reference image generation circuit 112, a stage control circuit 114, a lens control circuit 124, a blanking control circuit 126, a deflection control circuit 128, a retarding high-voltage power supply circuit 130, a storage device 109 such as a magnetic disk drive, a monitor 117, a memory 118, and a printer 119. The deflection control circuit 128 is connected to DAC (digital-to-analog conversion) amplifiers 144, 146 and 148. The DAC amplifier 146 is connected to the main deflector 208, and the DAC amplifier 144 is connected to the sub deflector 209. The DAC amplifier 148 is connected to the deflector 218.

The detection circuit 106 is connected to a chip pattern memory 123 which is connected to the comparison circuit 108. The stage 105 is driven by a drive mechanism 142 under the control of the stage control circuit 114. In the drive mechanism 142, for example, a drive system such as a three (x-, y-, and θ-)axis motor which provides drive in the directions of x, y, and θ in the stage coordinate system is configured, and can move in the x, y, and θ directions. A step motor, for example, can be used as each of these x, y, and θ motors (not shown). The movement position of the stage 105 is measured by the laser length measuring system 122, and supplied to the position circuit 107. Based on the principle of laser interferometry, the laser length measuring system 122 measures the position of the stage 105 by receiving a reflected light from the mirror 216.

The electron gun 201 is controlled by the high-voltage power supply circuit 121. The electromagnetic lenses 205, 206, 207 (objective lens), and 224, and the beam separator 214 are controlled by the lens control circuit 124. The bundle blanking deflector 212 is composed of two or more electrodes, and each electrode is controlled by the blanking control circuit 126 through a DAC amplifier (not shown). The sub deflector 209 is composed of four or more electrodes, and each electrode is controlled by the deflection control circuit 128 through the DAC amplifier 144. The main deflector 208 is composed of four or more electrodes, and each electrode is controlled by the deflection control circuit 128 through the DAC amplifier 146. The deflector 218 is composed of four or more electrodes, and each electrode is controlled by the deflection control circuit 128 through the DAC amplifier 148. Further, the substrate 101 is electrically insulated from the stage 105, and a retarding voltage optimal for an inspection is applied from the retarding high-voltage power supply circuit 130.

FIG. 1 shows a configuration necessary for describing the embodiment 1. Other configuration generally necessary for the inspection apparatus 100 may also be included therein.

When an acceleration voltage (e.g., −50 kV) is applied from the high-voltage power supply circuit 121 to the cathode 10, using the Schottky effect, the electron beam 200 is emitted from the cathode 10. The emitted electron beam 200 is extracted by the extractor 14 (extraction electrode) to which an extraction potential (e.g., −45 kV) has been applied from the high-voltage power supply circuit 121, while the beam's spreading is suppressed by the suppressor 12 to which a bias potential (e.g., −50.3 kV) has been applied from the high-voltage power supply circuit 121. The extracted electron beam 200 travels toward the multi-stage electrodes 16, 18, 19, 23, 24, and 25. A desired control potential (e.g., −39 kV) is applied to the electrode 16 from the high-voltage power supply circuit 121. A desired control potential (e.g., −45.5 kV) is applied to the electrode 18 from the high-voltage power supply circuit 121. A desired control potential (e.g., −48 kV) is applied to the electrode 19 from the high-voltage power supply circuit 121. A desired control potential (e.g., −48 kV) is applied to the electrode 23 from the high-voltage power supply circuit 121. A desired control potential (e.g., −46.5 kV) is applied to the electrode 24 from the high-voltage power supply circuit 121. A desired control potential (e.g., −44 kV) is applied to the electrode 25 from the high-voltage power supply circuit 121. The electron beam 200 travels and decelerates while spreading by the electric field provided by the electrodes 16 and 18, and irradiates the region including the whole of a plurality of passage holes formed on the shaping aperture array substrate 21. Then, a portion of electron beam 200 individually passes through the plurality of passage holes, resulting in generating the multiple primary electron beams 20. An intermediate image plane of each beam of the generated multiple primary electron beams 20 is formed at the height position of the next electrode 23 by the electrical field (electric field) provided by the electrode 19, and the beams 20 are refracted to change its direction to a converging direction by the electric field provided by the electrode 23. Then, the multiple primary electron beams 20 having passed through the electrode 23 are accelerated and further converged by the electric field provided by the electrodes 24 and 25, and emitted from the electron gun 201 so as to travel into the electron beam column 102.

The multiple primary electron beams 20, having been emitted from the electron gun 201 and formed, are individually refracted by the electromagnetic lenses 205 and 206, and travel to the electromagnetic lens 207 (objective lens), while forming a crossover and an intermediate image, through the beam separator 214 disposed at the intermediate image position (I. I. P) of each beam of the multiple primary electron beams 20. Then, the electromagnetic lens 207 focuses the multiple primary electron beams 20 onto the substrate 101. The multiple primary electron beams 20 having been focused on the substrate 101 (target object) by the electromagnetic lens 207 (objective lens) are collectively deflected by the main deflector 208 and the sub deflector 209 to irradiate respective beam irradiation positions on the substrate 101. When all of the multiple primary electron beams 20 are collectively deflected by the bundle blanking deflector 212, they deviate from the hole in the center of the limiting aperture substrate 213 and blocked by the limiting aperture substrate 213. On the other hand, the multiple primary electron beams 20 which were not deflected by the bundle blanking deflector 212 pass through the hole in the center of the limiting aperture substrate 213 as shown in FIG. 1. Blanking control is provided by On/Off of the bundle blanking deflector 212, and thus On/Off of the multiple beams is collectively controlled. In this way, the limiting aperture substrate 213 blocks the multiple primary electron beams 20 which were deflected to be in the “beam Off condition” by the bundle blanking deflector 212. Then, the multiple primary electron beams 20 for inspection (for image acquisition) are formed by the beams having been made during from becoming “beam On” to becoming “beam Off” and having passed through the limiting aperture substrate 213.

When desired positions on the substrate 101 are irradiated with the multiple primary electron beams 20, a flux of secondary electrons (multiple secondary electron beams 300) including reflected electrons, each corresponding to each of the multiple primary electron beams 20, is emitted from the substrate 101 due to the irradiation with the multiple primary electron beams 20.

The multiple secondary electron beams 300 emitted from the substrate 101 travel to the beam separator 214 through the electromagnetic lens 207.

Here, the beam separator 214 generates an electric field and a magnetic field to be perpendicular to each other in a plane orthogonal to the traveling direction of the center beam (that is, the electron trajectory center axis) of the multiple primary electron beams 20. The electric field exerts a force in a fixed direction regardless of the traveling direction of electrons. In contrast, the magnetic field exerts a force according to Fleming's left-hand rule. Therefore, the direction of force acting on electrons can be changed depending on the electron entering direction. With respect to the multiple primary electron beams 20 entering the beam separator 214 from above, since the forces due to the electric field and the magnetic field cancel each other out, the beams 20 travel straight downward. In contrast, with respect to the multiple secondary electron beams 300 entering the beam separator 214 from below, since both the forces due to the electric field and the magnetic field are exerted in the same direction, the beams 300 are bent obliquely upward, and separated from the multiple primary electron beams 20.

The multiple secondary electron beams 300 having been bent obliquely upward and separated from the multiple primary electron beams 20 are further bent by the deflector 218, and projected onto the multi-detector 222 while being refracted by the electromagnetic lens 224. The multi-detector 222 detects the projected multiple secondary electron beams 300. Onto the multi-detector 222, reflected electrons and secondary electrons may be projected, or it is also acceptable that reflected electrons are emitted along the way and remaining secondary electrons are projected. The multi-detector 222 includes a two-dimensional sensor. Then, at a corresponding region of the two-dimensional sensor, each secondary electron of the multiple secondary electron beams 300 collides with the corresponding region to generate electrons, and secondary electron image data is generated for each pixel. In other words, in the multi-detector 222, a detection sensor is disposed for each primary electron beam of the multiple primary electron beams 20. Then, the detection sensor detects a corresponding secondary electron beam emitted by irradiation with each primary electron beam. Therefore, each of a plurality of detection sensors in the multi-detector 222 detects an intensity signal of a secondary electron beam for an image, which is generated due to irradiation with an associated corresponding primary electron beam 301. The intensity signal detected by the multi-detector 222 is output to the detection circuit 106.

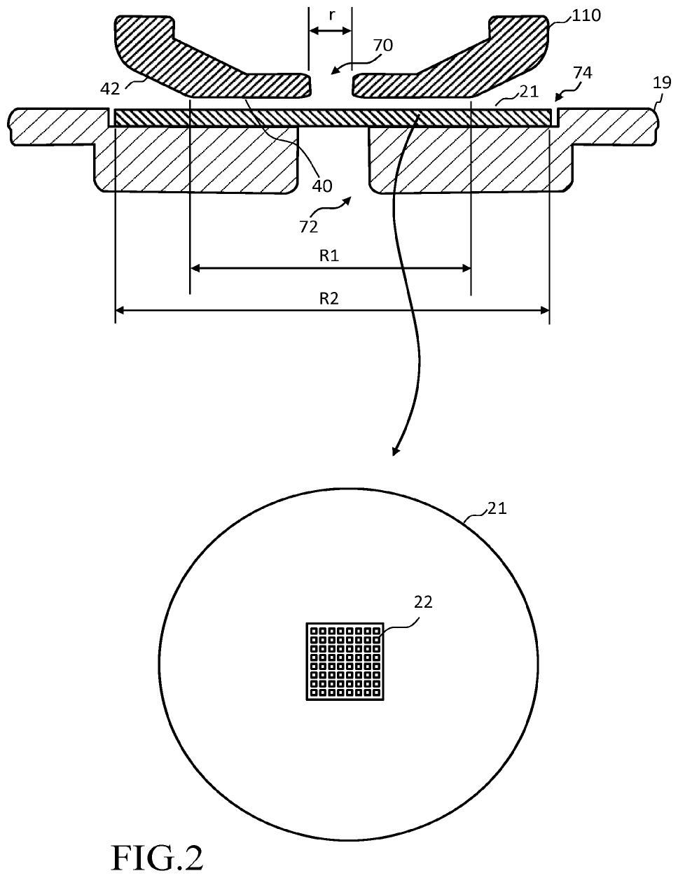

FIG. 2 is a diagram illustrating an example of a sectional configuration of a shaping aperture array substrate and neighboring electrodes in the multi-stage electrodes in the electron gun according to the embodiment 1. FIG. 2 shows two electrodes 18 and 19 in the multi-stage electrodes 16, 18, 19, 23, 24, and 25, and the shaping aperture array substrate 21 according to the embodiment 1. In the shaping aperture array substrate 21, as shown in FIG. 2, a plurality of passage holes 22 are formed in the center portion. FIG. 2 shows the case where 8×8 passage holes 22 are formed, for example. The number of the passage holes 22 is not limited to this number, and may be more or less than that. The multiple primary electron beams 20 are formed by letting portions of the electron beam 200 individually pass through the plurality of holes 22. The surface of the shaping aperture array substrate 21 is substantially formed by a plane although there are some irregularities.

The electrode 18 (first electrode) is disposed at the cathode 10 (emission source) side (upstream side of the central axis advancing direction of the electron beam 200) with respect to the shaping aperture array substrate 21. At the center of the electrode 18, there is formed an opening 70 (first opening) having a diameter r through which the electron beam 200 can pass. Further, the electrode 18 has an opposing plane 40 which is located at the emission source side of the shaping aperture array substrate 21 and facing the surface of the shaping aperture array substrate 21, and whose outer diameter R1 is smaller than the outer diameter R2 of the shaping aperture array substrate 21. The opposing plane 40 is formed circularly, for example. The electrode 18 further has a surface 42 which is connected to the outer periphery of the opposing plane 40, and extends toward the outside in the direction departing from the plane including the surface of the shaping aperture array substrate 21. The surface 42 is formed in a club shape, for example, like a truncated cone, expanding toward the upstream side of the central axis of the electron beam 200. The portion connected from the opposing plane 40 to the surface 42 is not sharpened but R-processed.

The electrode 19 (second electrode) is disposed to be adjacent and on the downstream side of the central axis advancing direction of the electron beam 200 with respect to the electrode 18. At the center of the electrode 19, there is formed an opening 72 (second opening) through which all of the multiple primary electron beams 20 can pass. The electrode 19 adheringly and fixedly supports the outer periphery of the shaping aperture array substrate 21. In the example of FIG. 2, the shaping aperture array substrate 21 is disposed on the counterbore hole (concave portion) which is a little larger than the outer diameter R2 of the shaping aperture array substrate 21. Therefore, a space 74 is formed between the outer peripheral edge of the shaping aperture array substrate 21 and the inner wall of the counterbore hole.

The multi-stage electrodes 16, 18, 19, 23, 24 and 25, namely including the two electrodes 18 and 19, are individually applied with control potentials from the high-voltage power supply circuit 121, and provide electrical fields (electric fields) to the electron beam 200 (or multiple primary electron beams 20). A control potential of −39 kV, for example, is applied to the electrode 16. A control potential (first control potential) of −45.5 kV, for example, is applied to the electrode 18. A control potential (second control potential) of −48 kV, for example, is applied to the electrode 19. Therefore, after the electron beam 200 extracted by the extractor 14 which is applied with an electric potential of −45 kV, for example, is accelerated by the electric field provided by the electrode 16, it is decelerated by the electric field provided by the electrode 18, and further decelerated by the electric field provided by the electrode 19. The electron beam 200 in the decelerated state irradiates the surface of the shaping aperture array substrate 21. At this time, an electrical field (electric field) is generated by an electric potential difference between the potential of the electrode 18 and the potential of the shaping aperture array substrate 21 through the electrode 19. In the case of FIG. 2, between the surface of the shaping aperture array substrate 21 and the opposing plane 40 of the electrode 18, an electric field between the flat-plate electrodes is generated, and substantially parallel dense potential curves are aligned therein.

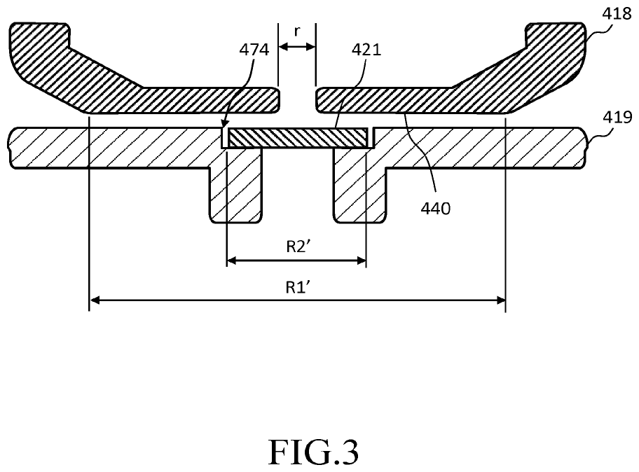

FIG. 3 is a diagram illustrating an example of a sectional configuration of a shaping aperture array substrate and neighboring electrodes in the multi-stage electrodes in the electron gun according to a comparative example of the embodiment 1. The comparative example of FIG. 3 shows two electrodes 418 and 419 corresponding to the two electrodes 18 and 19 in the multi-stage electrodes 16, 18, 19, 23, 24, and 25 according to the embodiment 1, and a shaping aperture array substrate 421. The surface of the shaping aperture array substrate 421 is substantially formed by a plane although there are some irregularities.

The electrode 418 has an opposing plane 440 which is facing the surface of the shaping aperture array substrate 421, and whose outer diameter R1′ is larger than the outer diameter R2′ of the shaping aperture array substrate 421.

The electrode 419 adheringly and fixedly supports the outer periphery of the shaping aperture array substrate 421. In the example of FIG. 3, the shaping aperture array substrate 421 is disposed on the counterbore hole which is a little larger than the outer diameter R2′ of the shaping aperture array substrate 421. Therefore, a space 474 is formed between the outer peripheral edge of the shaping aperture array substrate 421 and the inner wall of the counterbore hole.

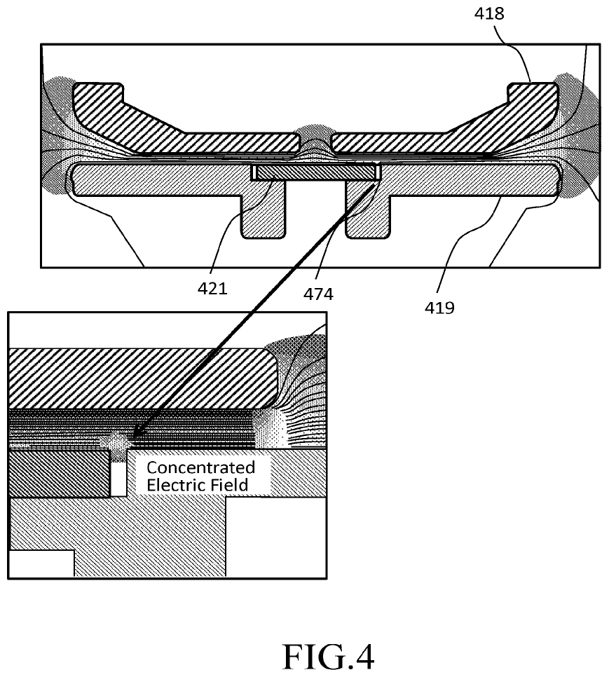

FIG. 4 is a diagram illustrating an example of an electric field near the shaping aperture array substrate in the multi-stage electrodes in the electron gun according to a comparative example of the embodiment 1. A control potential of, for example, −10.5 kV is applied to the electrode 418. A control potential of, for example, −13 kV is applied to the electrode 419. As shown in FIG. 4, the electric field is concentrated at a position of the space 474 between the outer peripheral edge of the shaping aperture array substrate 421 and the inner wall of the counterbore hole. Therefore, a discharge due to the electric field concentration is induced near the space 474. If an electric discharge occurs, potentials applied to the electrodes 18 and 19 become unstable. Consequently, the trajectory of the multiple primary electron beams formed by the shaping aperture array substrate 421 is affected. Therefore, it is necessary to prevent the electrode concentration at the end of the shaping aperture array substrate 421.

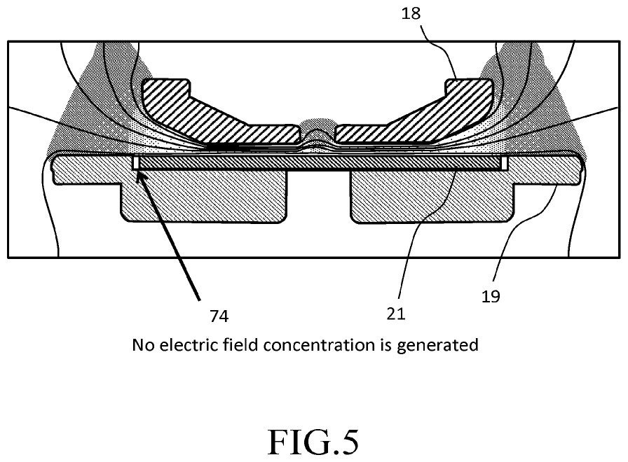

FIG. 5 is a diagram illustrating an example of an electric field near the shaping aperture array substrate in the multi-stage electrodes in the electron gun according to the embodiment 1. In the embodiment 1, the opposing plane 40 of the electrode 18 is formed to have an outer diameter R1 smaller than the outer diameter R2 of the shaping aperture array substrate 21. Thereby, the position of the space 74 between the outer peripheral edge of the shaping aperture array substrate 21 and the inner wall of the counterbore hole can be shifted to the position below the surface 42 which is outer than the opposing plane 40. As shown in FIG. 5, since the electric field generated between the surface of the shaping aperture array substrate 21 and the opposing plane 40 of the electrode 18 is the one between the flat-plate electrodes, substantially parallel dense potential curves are aligned therein. However, the arrangement of potential curves of the electric field between the surface 42 and the surface of the shaping aperture array substrate 21 is rougher than that of the electric field between the opposing plane 40 and the surface of the shaping aperture array substrate 21, the electric field concentration near the space 74 can be prevented. Accordingly, inducing an electric discharge can be avoided.

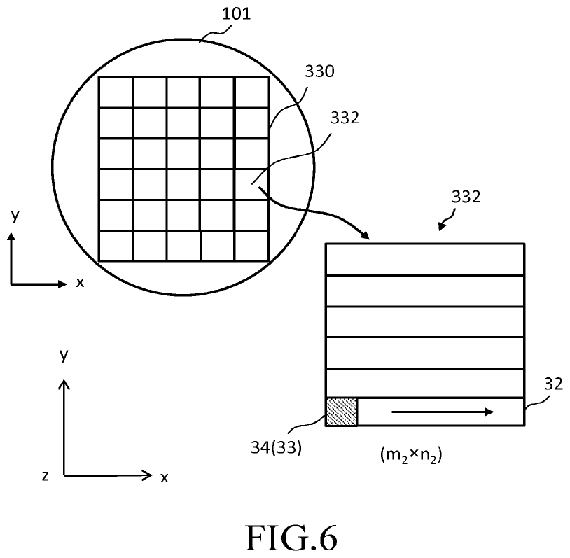

FIG. 6 is a diagram showing an example of a plurality of chip regions formed on a semiconductor substrate, according to the embodiment 1. In FIG. 6, in the case of the substrate 101 being a semiconductor substrate (wafer), a plurality of chips (wafer dies) 332 in a two-dimensional array are formed in an inspection region 330 of the semiconductor substrate (wafer). With respect to each chip 332, a mask pattern for one chip formed on an exposure mask substrate is reduced to ¼, for example, and exposed/transferred onto each chip 332 by an exposure device (stepper) (not shown). The region of each chip 332 is divided, for example, in the y direction into a plurality of stripe regions 32 by a predetermined width. The scanning operation by the image acquisition mechanism 150 is carried out for each stripe region 32, for example. The operation of scanning the stripe region 32 advances relatively in the x direction while the stage 105 is moved in the −x direction, for example. Each stripe region 32 is divided in the longitudinal direction into a plurality of multi-scan unit regions 33. Beam moving to a target multi-scan unit region 33 is achieved by collectively deflecting all the multiple primary electron beams 20 by the main deflector 208.

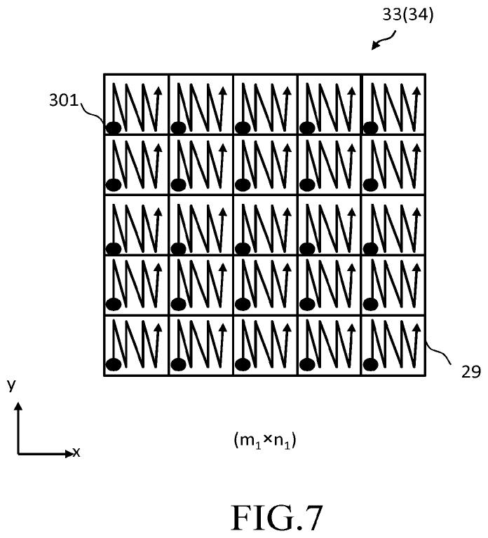

FIG. 7 is a diagram illustrating a scanning operation with multiple beams according to the embodiment 1. FIG. 7 shows the case of the multiple primary electron beams 20 of 5 rows×5 columns. An irradiation region 34 which can be irradiated by one irradiation with the multiple primary electron beams 20 is defined by (x direction size obtained by multiplying a beam pitch in the x direction of the multiple primary electron beams 20 on the substrate 101 by the number of beams in the x direction)×(y direction size obtained by multiplying a beam pitch in the y direction of the multiple primary electron beams 20 on the substrate 101 by the number of beams in the y direction). Preferably, the width of each stripe region 32 is set to be the same as the size in the y direction of the irradiation region 34, or to be the size reduced by the width of the scanning margin. In the case of FIGS. 6 and 7, the irradiation region 34 and the multi-scan unit region 33 are of the same size. However, it is not limited thereto. The irradiation region 34 may be smaller than the multi-scan unit region 33, or larger than it. Each beam of the multiple primary electron beams 20 irradiates and scans the inside of a sub-irradiation region 29 which is surrounded by the beam pitch in the x direction and the beam pitch in the y direction and in which the beam concerned itself is located. Each primary electron beam 301 of the multiple primary electron beams 20 is associated with any one of the sub-irradiation regions 29 which are different from each other. At the time of each shot, each primary electron beam 301 is applied to the same position in the associated sub-irradiation region 29. The primary electron beam 301 is moved in the sub-irradiation region 29 by collective deflection of all the multiple primary electron beams 20 by the sub deflector 209. By repeating this operation, the inside of one sub-irradiation region 29 is irradiated, in order, with one primary electron beam 301. Then, when scanning of one sub-irradiation region 29 is completed, the irradiation position is moved to an adjacent multi-scan unit region 33 in the same stripe region 32 by collectively deflecting all of the multiple primary electron beams 20 by the main deflector 208. By repeating this operation, the inside of the stripe region 32 is irradiated in order. After completing scanning of one stripe region 32, the irradiation position is moved to the next stripe region 32 by moving the stage 105 and/or by collectively deflecting all of the multiple primary electron beams 20 by the main deflector 208. As described above, by irradiation with each primary electron beam 301, a secondary electron image of each sub-irradiation region 29 is acquired. By combining secondary electron images of respective sub-irradiation regions 29, a secondary electron image of the multi-scan unit region 33, a secondary electron image of the stripe region 32, or a secondary electron image of the chip 332 is configured.

It is also preferable to group, for example, a plurality of chips 332 aligned in the x direction in the same group, and to divide each group into a plurality of stripe regions 32 by a predetermined width in the y direction, for example. Then, moving between stripe regions 32 is not limited to moving per chip 332, and it is also preferable to move per group.

When the multiple primary electron beams 20 irradiate the substrate 101 while the stage 105 is continuously moving, the main deflector 208 executes a tracking operation by performing collective deflection so that the irradiation position of the multiple primary electron beams 20 may follow the movement of the stage 105. Therefore, the emission position of the multiple secondary electron beams 300 changes every second with respect to the trajectory central axis of the multiple primary electron beams 20. Similarly, when the inside of the sub-irradiation region 29 is scanned, the emission position of each secondary electron beam changes every second in the sub-irradiation region 29. Thus, the deflector 218 collectively deflects the multiple secondary electron beams 300 so that each secondary electron beam whose emission position has changed as described above may be applied to a corresponding detection region of the multi-detector 222.

For acquiring an image, as described above, the multiple primary electron beams 20 are applied to the substrate 101 so that the multi-detector 222 may detect the multiple secondary electron beams 300 emitted from the substrate 101 due to the irradiation with the multiple primary electron beams 20. Detected data (measured image data: secondary electron image data: inspection image data) on a secondary electron of each pixel in each sub-irradiation region 29 detected by the multi-detector 222 is output to the detection circuit 106 in order of measurement. In the detection circuit 106, the detected data in analog form is converted into digital data by an A-D converter (not shown), and stored in the chip pattern memory 123. Then, the acquired measured image data is transmitted to the comparison circuit 108, together with information on each position from the position circuit 107.

The reference image generation circuit 112 generates a reference image corresponding to a frame image being an inspection unit image, based on design data serving as a basis of a plurality of figure patterns formed on the substrate 101. Specifically, it operates as follows: First, design pattern data is read from the storage device 109 through the control computer 110, and each figure pattern defined by the read design pattern data is converted into image data of binary or multiple values.

Basic figures defined by the design pattern data as described above are, for example, rectangles and triangles. For example, there is stored figure data defining the shape, size, position, and the like of each pattern figure by using information, such as coordinates (x, y) of the reference position of the figure, lengths of sides of the figure, and a figure code serving as an identifier for identifying the figure type such as a rectangle, a triangle and the like.

When design pattern data serving as the figure data is input to the reference image generation circuit 112, the data is developed into data of each figure. Then, a figure code, figure dimensions, and the like indicating the figure shape of each figure data are interpreted. Then, the reference image generation circuit 112 develops each figure data to design pattern image data of binary or multiple values as a pattern to be arranged in squares in units of grids of predetermined quantization dimensions, and outputs the developed data. In other words, the reference image generation circuit 112 reads design data, calculates the occupancy of a figure in the design pattern, for each square region obtained by virtually dividing the inspection region into squares in units of predetermined dimensions, and outputs n-bit occupancy data. For example, it is preferable to set one square as one pixel. Assuming that one pixel has a resolution of 1/2⁸(=1/256), the occupancy rate in each pixel is calculated by allocating sub regions each being 1/256 to the region of a figure arranged in the pixel. Then, it becomes 8-bit occupancy data. Such square regions (inspection pixels) may be corresponding to pixels of measured data.

Next, the reference image generation circuit 112 performs filtering processing on design image data of a design pattern which is image data of a figure, using a predetermined filter function. Thereby, it is possible to match the design image data being design side image data, whose image intensity (gray scale level) is represented by digital values, with image generation characteristics obtained by irradiation with the multiple primary electron beams 20. The generated image data for each pixel of a reference image is output to the comparison circuit 108.

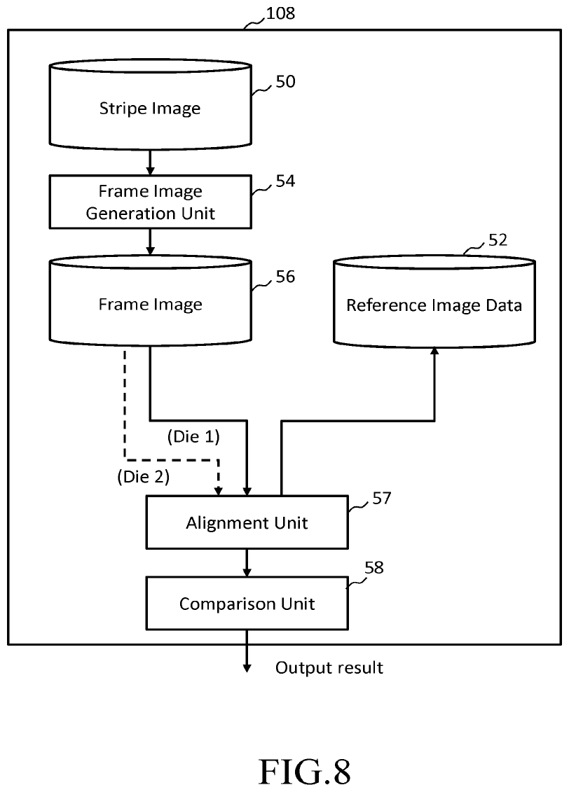

FIG. 8 is a diagram showing an example of an internal configuration of a comparison circuit according to the embodiment 1. In FIG. 8, storage devices 50, 52 and 56, such as magnetic disk drives, a frame image generation unit 54, an alignment unit 57, and a comparison unit 58 are arranged in the comparison circuit 108. Each of the “units” such as the frame image generation unit 54, the alignment unit 57 and the comparison unit 58 includes processing circuitry. As the processing circuitry, an electric circuit, computer, processor, circuit board, quantum circuit, semiconductor device, or the like can be used. Further, common processing circuitry (same processing circuitry), or different processing circuitry (separate processing circuitry) may be used for each of the “units”. Input data required in the frame image generation unit 54, the alignment unit 57 and the comparison unit 58, or a calculated result is stored in a memory (not shown) or in the memory 118 each time.

According to the embodiment 1, the sub-irradiation region 29 acquired by scanning with one primary electron beam 301 is further divided into a plurality of frame regions.

The frame region is used as a unit region of the inspection image. In order to prevent missing an image, it is preferable that margin regions overlap each other in each frame region. The frame region is set to be ¼ of the sub irradiation region 29 which is obtained by dividing the sub irradiation region 29 by two each in the x direction and the y direction, for example.

In the comparison circuit 108, transmitted image data (inspection image) of the stripe region 32 is temporarily stored in the storage device 50. Similarly, transmitted reference image data is temporarily stored, as a reference image of each frame region, in the storage device 52.

The frame image generation unit 54 reads image data from the storage device 50, and generates a frame image for every frame region. The generated frame image is stored in the storage device 56.

The alignment unit 57 reads a frame image serving as an inspection image, and a reference image corresponding to the frame image concerned, and provides alignment between both the images, based on units of sub-pixels smaller than pixels. For example, the alignment can be performed by a least-square method.

The comparison unit 58 compares the frame image (secondary electron image) and the reference image. In other words, the comparison unit 58 compares, for each pixel, reference image data with frame image. The comparison unit 58 compares them, for each pixel, based on predetermined determination conditions in order to determine whether there is a defect such as a shape defect. For example, if a difference in gray scale level for each pixel is larger than a determination threshold Th, it is determined that there is a defect. Then, the comparison result is output. It may be output to the storage device 109, the monitor 117, or the memory 118, or alternatively, output from the printer 119.

In the examples described above, the die-to-database inspection is performed. However, it is not limited thereto. The die-to-die inspection may be conducted. Now, the case of performing the die-to-die inspection will be described.

When performing the die-to-die inspection, the alignment unit 57 reads the frame image of the die (1) and the frame image of the die (2) where the same pattern as that of the die 1 is formed, and provides alignment between both the images based on units of sub-pixels smaller than pixels. For example, the alignment can be performed by a least-square method.

Then, the comparison unit 58 compares the frame image (inspection image) of the die 1 with the frame image (inspection image) of the die 2. The comparison unit 58 compares them, for each pixel, based on predetermined determination conditions in order to determine whether there is a defect such as a shape defect. For example, if a difference in gray scale level for each pixel is larger than the determination threshold Th, it is determined that there is a defect. Then, the comparison result is output. It is output to the storage device 109, the monitor 117, or the memory 118.

As described above, according to the embodiment 1, it is possible to avoid an electric discharge due to electrode concentration at the portion where the shaping aperture array substrate 21 (aperture array mechanism) is mounted on the electrode 19.

### Embodiment 2

The configuration of an inspection apparatus (electron beam irradiation apparatus) according to an embodiment 2 is the same as that of FIG. 1. Further, the contents of the embodiment 2 are the same as those of the embodiment 1 except for what is particularly described below.

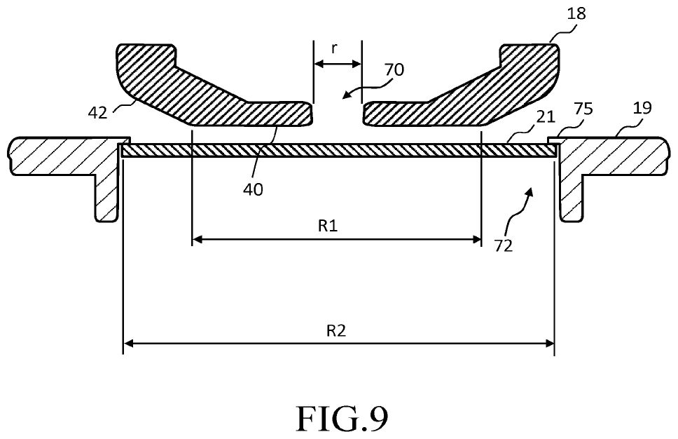

FIG. 9 is a diagram illustrating an example of a sectional configuration of a shaping aperture array substrate and neighboring electrodes in the multi-stage electrodes in the electron gun according to the embodiment 2. The contents of FIG. 9 are the same as those of FIG. 2 other than the sectional shape of the electrode 19 and the method of supporting the shaping aperture array substrate 21. Therefore, the electrode 18 has the opposing plane 40 which is located at the emission source side of the shaping aperture array substrate 21 and facing the surface of the shaping aperture array substrate 21, and whose outer diameter R1 is smaller than the outer diameter R2 of the shaping aperture array substrate 21. In the case of FIG. 9, the upper surface of the outer periphery of the shaping aperture array substrate 21 is supported by the electrode 19. The electrode 19 (second electrode) is disposed to be adjacent and on the downstream side of the central axis advancing direction of the electron beam 200 with respect to the electrode 18. At the center of the electrode 19, there is formed the opening 72 (second opening) through which all of the multiple primary electron beams 20 can pass and whose diameter is larger size than the outer diameter R2 of the shaping aperture array substrate 21. Further, at the upper edge of the opening 72, a flange 75 extends toward the inner periphery side. The electrode 19 supports the shaping aperture array substrate 21 such that the upper surface of the outer periphery of the shaping aperture array substrate 21 fixedly adheres to the backside of the flange 75. The length of the flange 75 extends to the position sufficiently distant from the outer diameter edge of the opposing plane 40 of the electrode 18.

The multi-stage electrodes 16, 18, 19, 23, 24 and 25, namely including the two electrodes 18 and 19, are individually applied with control potentials from the high-voltage power supply circuit 121, and provide electric fields (electrical fields) to the electron beam 200 (or multiple primary electron beams 20). A control potential of −39 kV, for example, is applied to the electrode 16. A control potential (first control potential) of −45.5 kV, for example, is applied to the electrode 18. A control potential (second control potential) of −48 kV, for example, is applied to the electrode 19. Therefore, an electrical field (electric field) is generated by an electric potential difference between the potential of the electrode 18 and the potential of the shaping aperture array substrate 21 through the electrode 19.

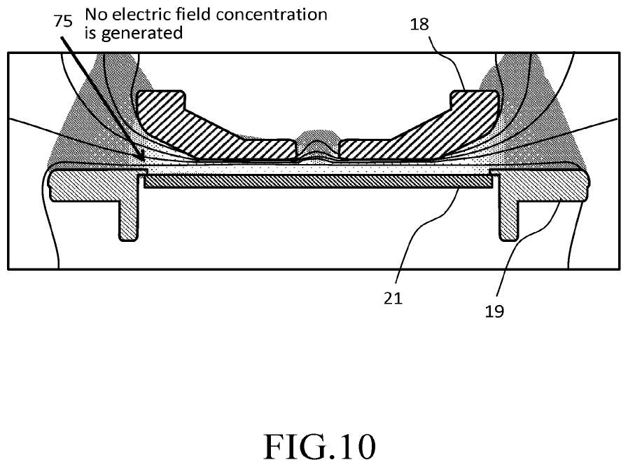

FIG. 10 is a diagram illustrating an example of an electric field near the shaping aperture array substrate in the multi-stage electrodes in the electron gun according to the embodiment 2. In the embodiment 2, similarly to the embodiment 1, the opposing plane 40 of the electrode 18 is formed to have an outer diameter R1 smaller than the outer diameter R2 of the shaping aperture array substrate 21. Thereby, the position of the flange 75 supporting the outer peripheral edge of the shaping aperture array substrate 21 can be shifted to the position below the surface 42 which is outer than the opposing plane 40. As shown in FIG. 10, between the surface of the shaping aperture array substrate 21 and the opposing plane 40 of the electrode 18, an electric field between the flat-plate electrodes is generated, and substantially parallel dense potential curves are aligned therein. Further, since a position level difference arises between the flange 75 and the surface of the shaping aperture array substrate 21, the electric field at this position changes depending on the level difference. However, the arrangement of potential curves of the electric field between the surface 42 and the surface of the shaping aperture array substrate 21 is rougher than that of the electric field between the opposing plane 40 and the surface of the shaping aperture array substrate 21, the electric field concentration near the flange 75 can be prevented. Accordingly, inducing an electric discharge can be avoided.

The other contents are the same as those of the embodiment 1.

As described above, according to the embodiment 2, even in the case where the upper surface of the outer periphery of the shaping aperture array substrate 21 is supported by the electrode 19, it is possible to avoid an electric discharge due to electrode concentration at the portion where the shaping aperture array substrate 21 is mounted on the electrode 19.

### Embodiment 3

The configuration of an inspection apparatus (electron beam irradiation apparatus) according to an embodiment 3 is the same as that of FIG. 1. Further, the contents of the embodiment 3 are the same as those of the embodiment 1 except for what is particularly described below.

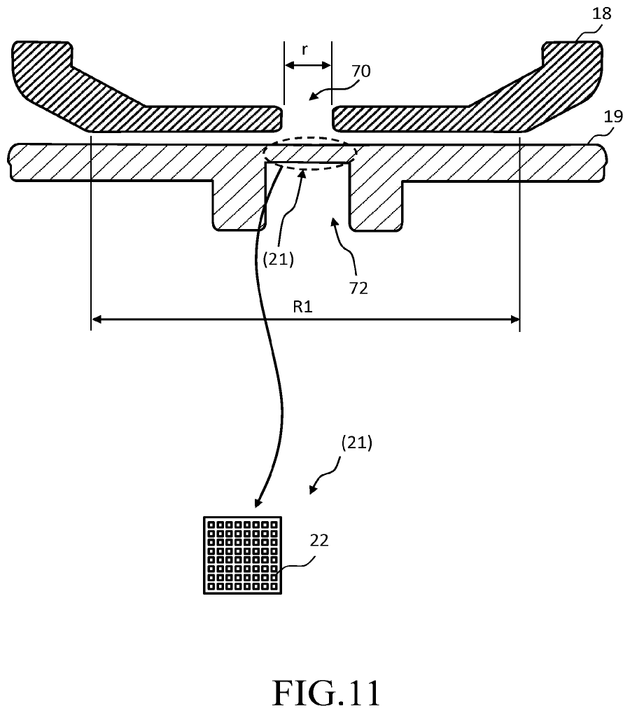

FIG. 11 is a diagram illustrating an example of a sectional configuration of a shaping aperture array mechanism and neighboring electrodes in the multi-stage electrodes in the electron gun according to the embodiment 3. At the center of one of the multi-stage electrodes 16, 18, 19, 23, 24, and 25 according to the embodiment 3, there are formed a plurality of passage holes 22 which form multiple primary electron beams 20 by letting portions of the electron beam 200 individually pass through the plurality of holes 22. At the centers of the remaining electrodes in the multi-stage electrodes 16, 18, 19, 23, 24, and 25, there are formed openings through which the electron beam 200 or the multiple primary electron beams 20 can pass individually. The example of FIG. 11 shows the two electrodes 18 and 19 in the multi-stage electrodes 16, 18, 19, 23, 24, and 25 according to the embodiment 3. In the case of FIG. 11, the plurality of passage holes 22 are formed, as a shaping aperture array, in the electrode 19 itself. FIG. 11 shows the case where 8×8 passage holes 22 are formed, for example. The number of the passage holes 22 is not limited to this number, and may be more or less than this. The multiple primary electron beams 20 are formed by letting portions of the electron beam 200 individually pass through the plurality of holes 22. The surface of the electrode 19 is substantially formed by a plane although there are some irregularities. By forming the passage hole 22 in the electrode 19 itself, the space 74 as described in the embodiment 1 can be eliminated. The shape of the electrode 18 is the same as that of FIG. 2. In other words, the electrode 18 has an opposing plane which is located at the emission source side of the electrode 19 and facing the surface of the electrode 19, and whose outer diameter is smaller than the surface outer diameter of the electrode 19. Since the electric field generated between the surface of the electrode 19 where the shaping aperture array is formed and the opposing plane 40 of the electrode 18 is the one between the flat-plate electrodes, substantially parallel dense potential curves are aligned therein. Further, since the space 74 as described in the embodiment 1 and the flange 75 as described in the embodiment 2 do not exist, there is no place where electric field concentration is generated. Accordingly, inducing an electric discharge can be avoided.

The other contents are the same as those of the embodiment 1.

As described above, according to the embodiment 3, even in the case in which a shaping aperture array is formed in the electrode 19 itself, it is possible to avoid an electric discharge due to electrode concentration at the portion where the shaping aperture array is formed in the electrode 19.

In the above description, a series of “ . . . circuits” includes processing circuitry, which includes an electric circuit, a computer, a processor, a circuit board, a quantum circuit, a semiconductor device, or the like. Each “ . . . circuit” may use common processing circuitry (the same processing circuitry), or different processing circuitry (separate processing circuitry). A program for causing a processor, etc. to execute processing may be stored in a recording medium, such as a magnetic disk drive, magnetic tape drive, FD, ROM (Read Only Memory) or the like. For example, the position circuit 107, the comparison circuit 108, the reference image generation circuit 112, the stage control circuit 114, the lens control circuit 124, the blanking control circuit 126, and the deflection control circuit 128 may be configured by at least one processing circuit described above.

Embodiments have been explained referring to specific examples as described above. However, the present invention is not limited to these specific examples. Although FIG. 1 shows the case of using a Schottky type cathode as the cathode 10 of the electron gun 201, it is not limited thereto. For example, another cathode such as a heat cathode may also be used. Further, as the configuration of the electrode 18, the tapered surface 42 continues outside the opposing plane 40 in the examples described above, it is not limited thereto. The electrode 18 may be a tabular substrate formed by the opposing plane 40.

While the apparatus configuration, control method, and the like not directly necessary for explaining the present invention are not described, some or all of them can be appropriately selected and used on a case-by-case basis when needed.

Further, any other electron gun and electron beam irradiation apparatus that include elements of the present invention and that can be appropriately modified by those skilled in the art are included within the scope of the present invention.

### INDUSTRIAL APPLICABILITY

The present invention relates to an electron gun and an electron beam irradiation apparatus, which can be applied to an electron gun that emits multiple beams mounted in an apparatus for irradiating multiple electron beams.

### REFERENCE SIGNS LIST

10 Cathode
11 Vacuum Vessel
12 Suppressor
14 Extractor
16, 18, 19, 23, 24, 25, 418, 419 Electrode
20 Multiple Primary Electron Beams
21, 421 Shaping Aperture Array Substrate
22 Passage Hole
29 Sub Irradiation Region
32 Stripe Region
33 Multi-scan Unit Region
34 Irradiation Region
40, 440 Opposing Plane
42 Surface
50, 52, 56 Storage Device
54 Frame Image Generation Unit
57 Alignment Unit
58 Comparison Unit
70, 72 Opening
74, 474 Space
75 Flange
100 Inspection Apparatus
101 Substrate
102 Electron Beam Column
103 Inspection Chamber
105 Stage
106 Detection Circuit
107 Position Circuit
108 Comparison Circuit
109 Storage Device
110 Control Computer
112 Reference Image Generation Circuit
114 Stage Control Circuit
117 Monitor
118 Memory
119 Printer
120 Bus
121 High Voltage Power Supply Circuit
122 Laser Length Measuring System
123 Chip Pattern Memory
124 Lens Control Circuit
126 Blanking Control Circuit
128 Deflection Control Circuit
130 Retarding High-voltage Power Supply Circuit
142 Drive Mechanism
144, 146, 148 DAC amplifier
150 Image Acquisition Mechanism
160 Control System Circuit
201 Electron Gun
205, 206, 207, 224 Electromagnetic Lens
208 Main Deflector
209 Sub Deflector
212 Bundle Blanking Deflector
213 Limiting Aperture Substrate
214 Beam Separator
216 Mirror
218 Deflector
222 Multi-Detector
300 Multiple Secondary Electron Beams
301 Primary Electron Beam
330 Inspecting Region
332 Chip

1. An electron gun comprising:
an emission source configured to emit an electron beam;
an aperture array substrate, where a plurality of passage holes are formed, configured to form multiple beams by letting portions of the electron beam individually pass through the plurality of passage holes; and
a first electrode, where a first opening through which the electron beam can pass is formed, configured to include an opposing plane which is located at a side of the emission source with respect to the aperture array substrate and facing a surface of the aperture array substrate and whose outer diameter is smaller than an outer diameter of the aperture array substrate, the first electrode configured to be applied with a first control potential.

2. The electron gun according to claim 1, wherein
a silicon substrate is used as a main material of the aperture array substrate, further comprising:
a second electrode, where a second opening through which all of the multiple beams can pass is formed, configured to support an outer periphery of the aperture array substrate adheringly and fixedly, and to be applied with a second control potential.

3. The electron gun according to claim 1, wherein
the first electrode further includes a surface which is connected to an outer periphery of the opposing plane and extends toward outside in a direction departing from a plane including the surface of the aperture array substrate.

4. The electron gun according to claim 2, wherein
the second electrode includes a concave portion which supports a backside of the aperture array substrate.

5. An electron beam irradiation apparatus comprising:
an electron gun configured to include
an emission source to emit an electron beam,
an aperture array substrate, where a plurality of openings are formed, configured to form multiple beams by letting portions of the electron beam individually pass through the plurality of openings, and
a first electrode configured to include an opposing plane which is located at a side of the emission source with respect to the aperture array substrate and facing a surface of the aperture array substrate and whose outer diameter is smaller than an outer diameter of the aperture array substrate, and to provide an electric field between the first electrode and the aperture array substrate; and
an electron optical system configured to lead the multiple beams emitted from the electron gun to a target object.

6. The electron beam irradiation apparatus according to claim 5, wherein
a silicon substrate is used as a main material of the aperture array substrate, further comprising:
a second electrode, where a second opening through which all of the multiple beams can pass is formed, configured to support an outer periphery of the aperture array substrate adheringly and fixedly, and to be applied with a second control potential.

7. The electron beam irradiation apparatus according to claim 5, wherein
the first electrode further includes a surface which is connected to an outer periphery of the opposing plane and extends toward outside in a direction departing from a plane including the surface of the aperture array substrate.

8. The electron beam irradiation apparatus according to claim 6, wherein
the second electrode includes a concave portion which supports a backside of the aperture array substrate.

9. An electron gun comprising:
an emission source configured to emit an electron beam; and
multi-stage electrodes configured to provide an electric field to the electron beam, wherein
a plurality of passage holes which generate multiple beams by letting portions of the electron beam individually pass through the plurality of passage holes are formed at a center of one of the multi-stage electrodes, and
openings through which the electron beam can pass individually are formed at centers of remaining electrodes in the multi-stage electrodes, wherein
the multi-stage electrodes include a first electrode and a second electrode which are laminated with a space,
the plurality of passage holes are formed at a center of the second electrode; and
the first electrode includes an opposing plane which is located at a side of the emission source with respect to the second electrode and facing a surface of the second electrode and whose outer diameter is smaller than a surface outer diameter of the second electrode.

10. (canceled)
